(19) United States
(12) Patent Application Publication
(10) Pub. No.: US 2026/0307689 A1
(43) Pub. Date: Oct. 8, 2026

(54) RAIL GUIDED CARRIAGE SYSTEM AND METHOD FOR ESTIMATING ABNORMAL SECTION OF RAIL GUIDED CARRIAGE SYSTEM

(71) Applicant: MURATA MACHINERY, LTD, Kyoto-shi, Kyoto (JP)

(72) Inventors: Makoto KOBAYASHI, Kyoto-Shi (JP); Ryugo MURATA, Kyoto-shi (JP)

(21) Appl. No.: 19/478,001

(22) PCT Filed: Jan. 29, 2024
(86) PCT No.: PCT/JP2024/002692

§ 371 Date: Oct. 23, 2025

(30) Foreign Application Priority Data
Jul. 4, 2023 (JP) 2023-110038

(51) Int. Cl. B61K 9/08; B61B 3/02; B61L 23/04

(52) U.S. Cl. CPC B61K 9/08; B61B 3/02; B61L 23/04

(57) ABSTRACT

In a rail guided carriage system, a plurality of carriages are selectively travel movable along a plurality of sections of a track. The rail guided carriage system includes a controller configured or programmed to include a state information acquisition unit configured or programmed to acquire state information of the plurality of carriages, a travel history information acquisition unit configured or programmed to acquire travel history information of the plurality of carriages, and an abnormal section estimation unit configured or programmed to estimate an abnormal section based on the state information acquired by the state information acquisition unit and the travel history information acquired by the travel history information acquisition unit, the abnormal section being a section in which an abnormality has occurred among the plurality of sections.

### BACKGROUND OF THE INVENTION

### 1. Field of the Invention

The present disclosure relates to rail guided carriage systems and methods for estimating an abnormal section of the rail guided carriage systems.

### 2. Description of the Related Art

As a rail guided carriage system, there has been known a carriage system in which a plurality of carriages selectively travel in a plurality of sections (routes) of a track. As this type of technology, Japanese Unexamined Patent Publication No. 2011-221687 describes a carriage system that determines whether a cause of an abnormality is in a section (rail or the like) or a carriage when the carriage detects the abnormality while traveling using an abnormality detection sensor.

### SUMMARY OF THE INVENTION

By the way, in the rail guided carriage system, in order to more reliably prevent the subsequent spread of the damage, it is desirable to quickly estimate an abnormal section, which is a section where an abnormality has occurred (for example, a part of the magnetic plate is peeled off) in the track.

Therefore, example embodiments of the present invention provide rail guided carriage systems and methods for estimating an abnormal section of the rail guided carriage systems capable of quickly estimating an abnormal section of a track.

A rail guided carriage system according to an example embodiment of the present disclosure includes a plurality of carriages to selectively travel in a plurality of sections of a track, a controller configured or programmed to include a state information acquisition unit configured or programmed to acquire state information of the plurality of carriages, a travel history information acquisition unit configured or programmed to acquire travel history information of the plurality of carriages, and an abnormal section estimation unit configured or programmed to estimate an abnormal section based on the state information acquired by the state information acquisition unit and the travel history information acquired by the travel history information acquisition unit, the abnormal section being a section in which an abnormality has occurred among the plurality of sections.

When there is an abnormal section, it is discovered that the state of the carriage that has traveled in the abnormal section, among the plurality of carriages, changes (the LDM (linear DC motor) is damaged, the wheel is worn, or the like). Therefore, in a rail guided carriage system according to an example embodiment of the present disclosure, by evaluating the state information and the travel history information of the plurality of carriages in association with each other, it is possible to quickly estimate an abnormal section of the track and more reliably prevent the spread of the damage.

In a rail guided carriage system according to an example embodiment of the present disclosure, the state information may include information indicating damage states of the carriages, the travel history information may include information indicating a plurality of sections in which the carriages have traveled, and the abnormal section estimation unit may be configured or programmed to group the plurality of carriages into a first group of damaged carriages and a second group of undamaged carriages, and estimate the abnormal section based on at least one of a first frequency at which the plurality of carriages in the first group have traveled in each of the plurality of sections and a second frequency at which the plurality of carriages in the second group have traveled in each of the plurality of sections. In this case, it is possible to easily estimate an abnormal section of the track by grouping the plurality of carriages based on whether there is damage.

In a rail guided carriage system according to an example embodiment of the present disclosure, the abnormal section estimation unit may be configured or programmed to cause a display unit to display a heat map indicating each of the plurality of sections distinguished according to a difference value between the first frequency and the second frequency. In this case, it is possible to effectively visualize a degree of possibility of abnormality in the abnormal section among the plurality of sections.

In a rail guided carriage system according to an example embodiment of the present disclosure, the state information may include information indicating damage states of the carriages, the travel history information may include information indicating a plurality of sections in which the carriages have traveled, and the abnormal section estimation unit may be configured or programmed to estimate the abnormal section based on a ratio of a number of damaged or undamaged carriages with respect to the plurality of carriages that have traveled or have not traveled in each of the plurality of sections. It is discovered that the greater the bias in the ratio of the number of damaged carriages (or undamaged carriages) with respect to the plurality of carriages that have traveled (or have not traveled) in a certain section, the more likely it is that the section is an abnormal section (or is not an abnormal section). Therefore, in a rail guided carriage system according to an example embodiment of the present disclosure, it is possible to easily estimate an abnormal section of the track using such knowledge.

A controller in a rail guided carriage system according to an example embodiment of the present disclosure may be configured or programmed to further include a carriage selection unit configured or programmed to select, from among the plurality of carriages, some carriages related to a combination covering all of the plurality of sections of the track when the plurality of sections in which the some carriages have traveled are combined, in which the state information acquisition unit may be configured or programmed to acquire state information of the some carriages selected by the carriage selection unit, and the abnormal section estimation unit may be configured or programmed to estimate, as the abnormal section, a section in which a ratio of a number of damaged carriages with respect to the plurality of carriages that have traveled is equal to or greater than a threshold, among all of the plurality of the sections. In this case, it is possible to easily estimate an abnormal section among all the sections of the track.

A method for estimating an abnormal section of a rail guided carriage system according to an example embodiment of the present disclosure is a method for estimating an abnormal section that is a section in which an abnormality has occurred in a rail guided carriage system in which a plurality of carriages selectively travel in a plurality of sections of a track, the method including acquiring state information of the plurality of carriages, acquiring travel history information of the plurality of carriages, and estimating an abnormal section based on the state information acquired in the acquiring the state information and the travel history information acquired in the acquiring the travel history information, the abnormal section being a section in which an abnormality has occurred among the plurality of sections.

In this abnormal section estimation method as well, based on the state information and the travel history information of the plurality of carriages, it is possible to quickly estimate an abnormal section of the track and more reliably prevent the spread of the damage.

According to example embodiments of the present disclosure, it is possible to provide rail guided carriage systems and methods for estimating an abnormal section of the rail guided carriage systems capable of quickly estimating an abnormal section of a track.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view illustrating a rail guided carriage system according to a first example embodiment of the present invention.

FIG. 2 is a rear view illustrating an overhead traveling vehicle of FIG. 1.

FIG. 3 is a block diagram illustrating a controller of FIG. 1.

FIG. 4A is a diagram illustrating a first heat map. FIG. 4B is a diagram illustrating a second heat map.

FIG. 5 is a diagram illustrating an abnormal section heat map.

FIG. 6 is a flowchart illustrating an example of an abnormal section estimation method performed in the rail guided carriage system of FIG. 1.

FIG. 7 is a block diagram illustrating a controller of a rail guided carriage system according to a second example embodiment of the present invention.

FIG. 8 is a flowchart illustrating an example of an abnormal section estimation method performed in the rail guided carriage system of FIG. 7.

FIG. 9 is a diagram illustrating an example of display regarding a damage ratio displayed on a display of FIG. 7.

### DETAILED DESCRIPTION OF THE EXAMPLE EMBODIMENTS

Example embodiments of the present disclosure will be described below with reference to the drawings. In the description of the drawings, the same elements are denoted by the same reference signs and redundant description is omitted. In some drawings, “up”, “down”, “left”, “right”, “front”, and “back” directions are defined for convenience of explanation.

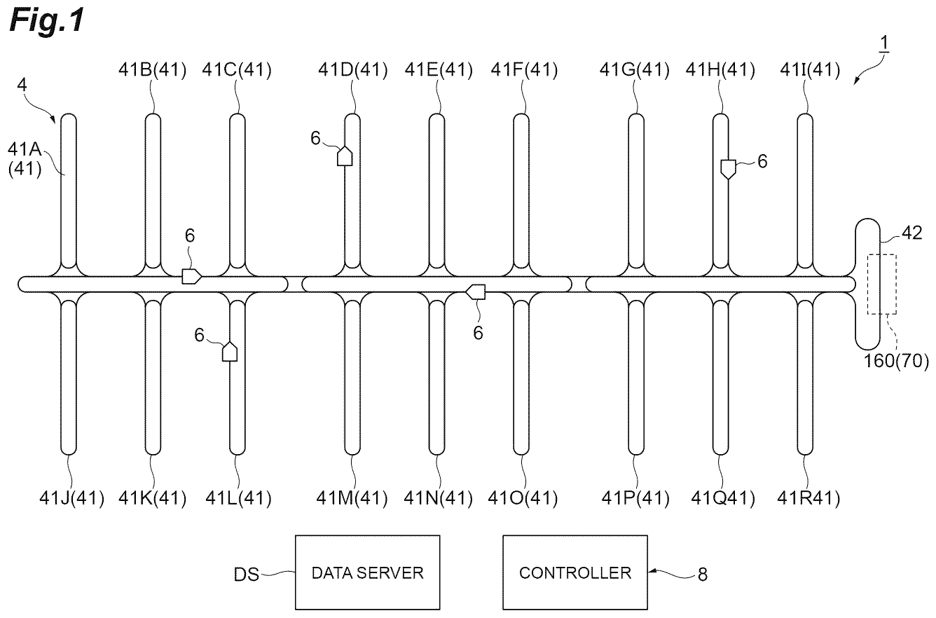

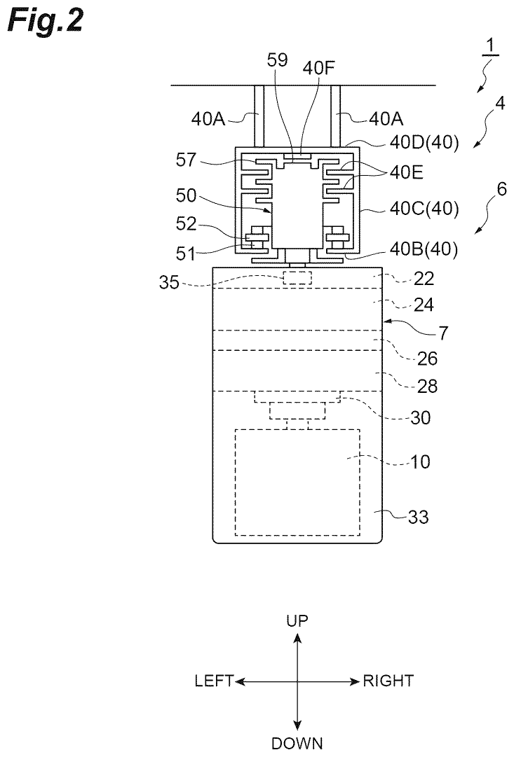

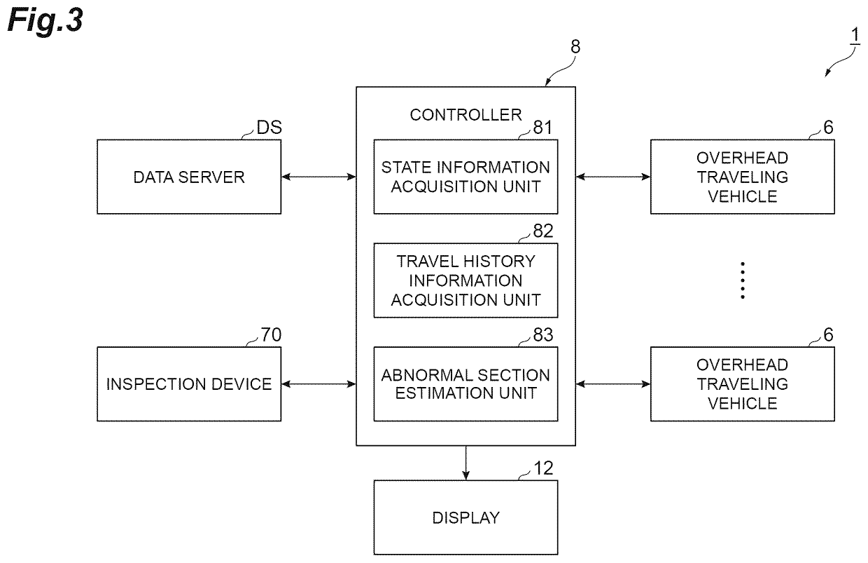

As illustrated in FIGS. 1 and 2, a rail guided carriage system 1 according to a first example embodiment is a system to transport an article 10 between a plurality of placement sections (not illustrated) using an overhead traveling vehicle (carriage) 6 movable along a track 4. Examples of the article 10 include containers such as a FOUP (front opening unified pod) storing a plurality of semiconductor wafers and a container storing a glass substrate, a container such as a reticle pod, and common parts. The placement section includes a buffer and a delivery port. In the rail guided carriage system 1, a plurality of overhead traveling vehicles 6 selectively travel in a plurality of sections 41 of the track 4. The rail guided carriage system 1 includes a track 4, a plurality of overhead traveling vehicles 6, a controller 8, a data server DS, and a display 12 (see FIG. 3).

The track 4 is laid, for example, in the vicinity of the ceiling that is a space above a worker's head. The track 4 is suspended from, for example, the ceiling. The track 4 is a predetermined one-way traveling path for the overhead traveling vehicles 6 to travel. The track 4 is supported by struts 40A and 40A. The track 4 includes a plurality of sections 41 of a main track, and a work section 42 provided with a work area 160 to inspect the overhead traveling vehicles 6. The section 41 is a portion between a branched point or a merging point and a branched point or a merging point in the track. The sections 41 may be, for example, intra-bays (intra-section tracks) provided independently of each other, or may be inter-bays (connection tracks) connecting a plurality of intra-bays. In the illustrated example, the track 4 includes at least a first section 41A to an eighteenth section 41R. The mode of the section 41 is not particularly limited as long as it is a part of the track 4.

The track 4 includes a tubular rail body 40 including a pair of lower surface portions 40B, a pair of side surface portions 40C and 40C, and a top surface portion 40D, and a power feeding unit 40E. The rail body 40 accommodates (encloses) a traveling unit 50 of the overhead traveling vehicle 6. The lower surface portions 40B extend in a traveling direction of the overhead traveling vehicle 6 and define a lower surface of the rail body 40. The lower surface portions 40B are plate-shaped structures on which a traveling roller 51 of the overhead traveling vehicle 6 rolls. The side surface portions 40C extend in the traveling direction of the overhead traveling vehicle 6 and define side surfaces of the rail body 40. The top surface portion 40D extends in the traveling direction of the overhead traveling vehicle 6 and defines an upper surface of the rail body 40. A magnetic plate 40F is attached to the top surface portion 40D.

The power feeding unit 40E supplies electric power to a power feeding core 57 of the overhead traveling vehicle 6, and transmits and receives signals to and from the power feeding core 57. The power feeding unit 40E is fixed to each of the pair of side surface portions 40C and 40C and extends along the traveling direction. The power feeding unit 40E supplies electric power to the power feeding core 57 in a contactless state. The magnetic plate 40F causes an LDM (Linear DC Motor) 59 of the overhead traveling vehicle 6 to generate a magnetic force for traveling or stopping. The magnetic plate 40F is fixed to the top surface portion 40D by a bracket or the like (not illustrated), and extends along the traveling direction. The overhead traveling vehicle 6 is a rail guided carriage driven by a linear motor.

The overhead traveling vehicle 6 travels on the track 4 to transport the article 10. The overhead traveling vehicle 6 traveling on the track 4 means that the traveling roller 51 of the overhead traveling vehicle 6 rolls on the lower surface portions 40B of the track 4. The overhead traveling vehicle 6 is configured to be able to transfer the article 10 thereon. The overhead traveling vehicle 6 is an unmanned traveling vehicle in an overhead traveling type. The number of overhead traveling vehicles 6 included in the rail guided carriage system 1 is not particularly limited, and is more than one. The overhead traveling vehicle 6 includes a main body 7, a traveling unit 50, and a controller 35.

The main body 7 includes a body frame 22, a lateral feeding unit 24, a θ drive 26, a lift driving unit 28, a lift platform 30, and a cover 33. The body frame 22 is connected to the traveling unit 50, and supports the lateral feeding unit 24, the O drive 26, the lift driving unit 28, the lift platform 30, and the cover 33. The lateral feeding unit 24 laterally feeds the O drive 26, the lift driving unit 28, and the lift platform 30 collectively in a direction orthogonal to the traveling direction of the track 4. The θ drive 26 turns at least one of the lift driving unit 28 and the lift platform 30 within a predetermined angle range in a horizontal plane. The lift driving unit 28 raises and lowers the lift platform 30 by winding and unwinding a suspending member such as a wire, a rope, or a belt. The lift platform 30 is provided with a chuck to freely hold or release the article 10. A pair of covers 33 are provided, for example, on the front and the back of the overhead traveling vehicle 6 in the traveling direction. The covers 33 prevent the article 10 from falling during transportation by extending and retracting claws or the like (not illustrated).

The traveling unit 50 causes the overhead traveling vehicle 6 to travel along the track 4. The traveling unit 50 includes various rollers such as a traveling roller 51 and a side roller 52, a power feeding core 57, and an LDM 59. The power feeding cores 57 are arranged so as to sandwich the LDM 59 in a left-right direction at the front and the back of the traveling unit 50. Power is fed in a contactless manner from the power feeding unit 40E disposed on the track 4 and various signals are transmitted and received in a contactless manner. The power feeding core 57 exchanges signals with the controller 35. The LDMs 59 are provided at the front and the back of the traveling unit 50. A magnetic force for traveling or stopping is generated, using an electromagnet, between the LDM 59 and the magnetic plate 40F disposed on the upper surface of the track 4.

The controller 35 may be an electronic control unit (ECU) including a CPU (central processing unit), a ROM (read only memory), and a RAM (random access memory). The controller 35 is configured or programmed to control various operations in the overhead traveling vehicle 6. Specifically, the controller 35 is configured or programmed to control the traveling unit 50, the lateral feeding unit 24, the θ drive 26, the lift driving unit 28, and the lift platform 30. The controller 35 can be configured, for example, as software in which a program stored in the ROM is loaded onto the RAM and executed by the CPU. The controller 35 may be configured as hardware by an electronic circuit or the like. The controller 35 may be configured or programmed to communicate with the controller 8 and the data server DS using the power feeding unit (power feeding line) 40E of the track 4, a feeder line, or the like.

The controller 35 transmits travel history information of the overhead traveling vehicle 6 to the data server DS. The travel history information is information regarding a route of the track 4 on which the overhead traveling vehicle 6 has traveled. The travel history information may include time information. For example, the travel history information may be information in which each section 41 of the track 4 on which the overhead traveling vehicle 6 has traveled and a time when the overhead traveling vehicle 6 traveled through each section are associated with each other.

The work area 160 is an area provided in the work section 42 to inspect a state of the overhead traveling vehicle 6. In the work area 160, an inspection device 70 is provided. The inspection device 70 inspects a state of the overhead traveling vehicle 6. The inspection device 70 inspects a damage state of (whether or not there is damage in) at least one of the traveling roller 51 and the LDM 59 of the traveling unit 50 included in the overhead traveling vehicle 6. Examples of the damage state include whether or not there is a scratch on the LDM 59 caused by a peeled-off portion of the magnetic plate 40F and whether or not there is a scratch formed on the traveling roller 51 and extending in the vertical direction.

The inspection device 70 includes a camera (inspection unit) that images at least one of the traveling roller 51 and the LDM 59. For example, in the inspection device 70, the damage state (whether or not there is a scratch or the like) may be determined by a worker observing an image captured by the camera, or the damage state may be automatically determined based on the image using an image analysis technique or the like. The inspection device 70 can communicate with the controller 8 and transmits a result of determining the damage state to the controller 8. When the worker determines the damage state, the worker may input the determination result into the inspection device 70.

The controller 8 is an electronic control unit (ECU) including a CPU, a ROM, a RAM, and the like. The controller 8 can be configured, for example, as software in which a program stored in the ROM is loaded onto the RAM and executed by the CPU. The controller 8 may be configured as hardware by an electronic circuit or the like. The controller 8 transmits a transportation command to the overhead traveling vehicle 6 to transport the article 10. In addition, the controller 8 transmits a travel command to the overhead traveling vehicle 6 to be inspected for a damage state to cause the overhead traveling vehicle 6 to travel to the work area 160.

As illustrated in FIG. 3, the controller 8 is configured or programmed to include a state information acquisition unit 81, a travel history information acquisition unit 82, and an abnormal section estimation unit 83 as functional components. The state information acquisition unit 81 is configured or programmed to acquire state information of the plurality of overhead traveling vehicles 6. Here, the state information acquisition unit 81 is configured or programmed to acquire, from the inspection device 70, results of determination of damage states of the plurality of overhead traveling vehicles 6 made by the inspection device 70 as the state information. The travel history information acquisition unit 82 is configured or programmed to acquire travel history information of the plurality of overhead traveling vehicles 6 from the data server DS.

The abnormal section estimation unit 83 is configured or programmed to estimate an abnormal section, which is a section 41 in which an abnormality has occurred, based on the state information acquired from the inspection device 70 by the state information acquisition unit 81 and the travel history information acquired from the data server DS by the travel history information acquisition unit 82. In the present example embodiment, the abnormal section estimation unit 83 is configured or programmed to group the plurality of overhead traveling vehicles 6 into a first group of damaged overhead traveling vehicles and a second group of undamaged overhead traveling vehicles based on the state information. The abnormal section estimation unit 83 is configured or programmed to estimate an abnormal section based on a first frequency at which the plurality of overhead traveling vehicles 6 in the first group have traveled in each of the plurality of sections 41 and a second frequency at which the plurality of overhead traveling vehicles 6 in the second group have traveled in each of the plurality of sections 41. Here, the abnormal section estimation unit 83 is configured or programmed to estimate a difference value between the first frequency and the second frequency in each of the plurality of sections 41 as a degree of possibility of abnormality in the abnormal section, and display a heat map indicating each of the plurality of sections 41 distinguished according to the difference value on the display 12.

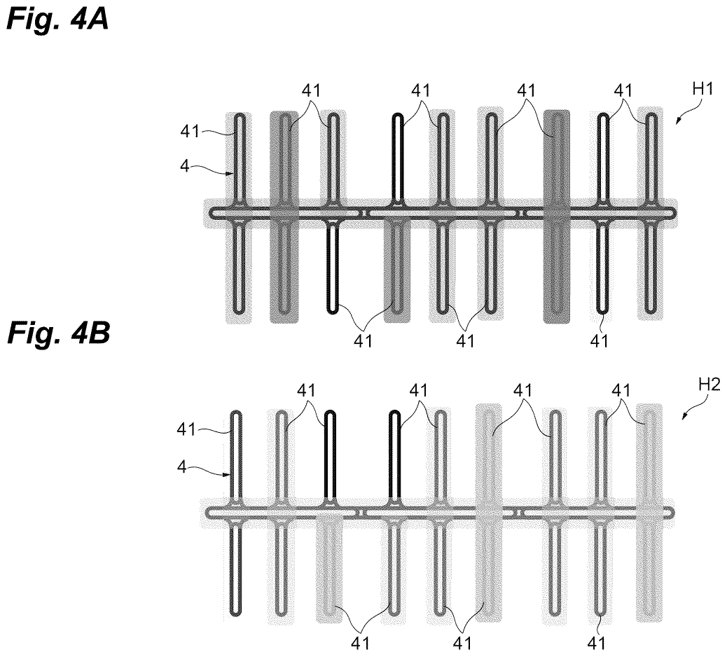

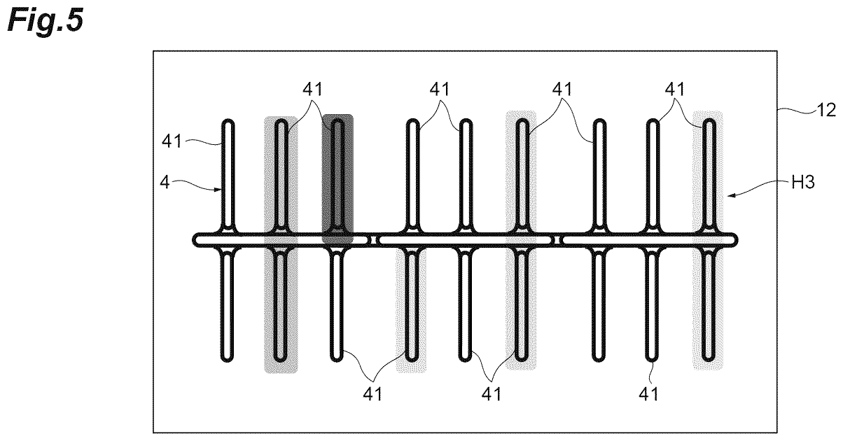

As an example, the abnormal section estimation unit 83 is configured or programmed to calculate the first frequency at which the plurality of overhead traveling vehicles 6 in the first group have traveled in each of the plurality of sections 41 based on the state information and the travel history information. The abnormal section estimation unit 83 is configured or programmed to generate a first heat map H1 (see FIG. 4A) in which each of the plurality of sections 41 is displayed darker as the first frequency is higher, is displayed lighter as the first frequency is lower, and is displayed with no color when no overhead traveling vehicle 6 has traveled therein. In addition, the abnormal section estimation unit 83 is configured or programmed to calculate the second frequency at which the plurality of overhead traveling vehicles 6 in the second group have traveled in each of the plurality of sections 41 based on the state information and the travel history information. The abnormal section estimation unit 83 is configured or programmed to generate a second heat map H2 (see FIG. 4A) in which each of the plurality of sections 41 is displayed darker as the second frequency is higher, is displayed lighter as the second frequency is lower, and is displayed with no color when no overhead traveling vehicle 6 has traveled therein. Then, as illustrated in FIG. 5, the abnormal section estimation unit 83 subtracts the second heat map H2 from the first heat map H1 to generate an abnormal section heat map H3, which is a difference heat map, as an estimation of an abnormal section. The controller 8 is configured or programmed to cause the display 12 to display the generated abnormal section heat map H3.

The data server DS is configured or programmed to be able to communicate with each overhead traveling vehicle 6 and the controller 8 in a wired or wireless manner. The data server DS receives and stores (accumulates) travel history information from each overhead traveling vehicle 6. The display 12 is a display unit that displays various types of information. The display 12 is connected to the controller 8, and displays the abnormal section heat map H3 under the control of the controller 8.

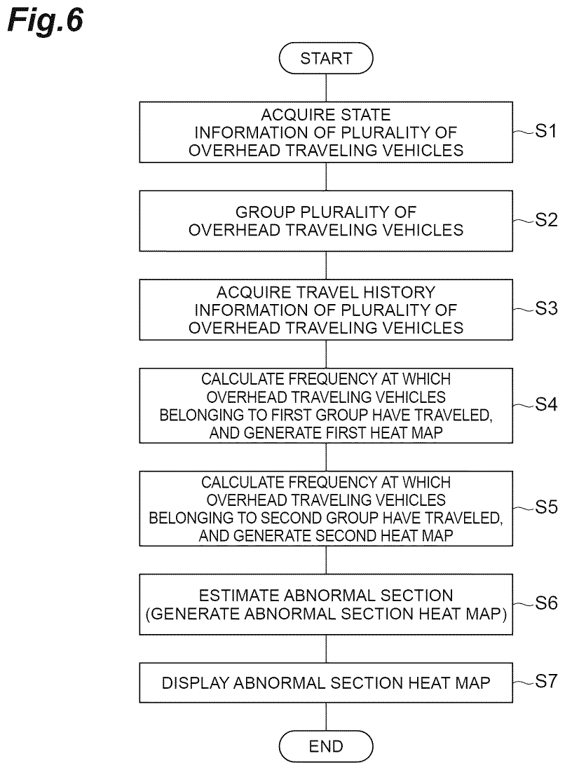

Next, an example of an abnormal section estimation method performed in the above-described rail guided carriage system 1 will be described with reference to a flowchart of FIG. 6.

In the rail guided carriage system 1, for example, the timing at which the inspection device 70 determines for the first time that there is damage is used as a trigger, and the following processing is performed by the controller 8 after a predetermined time has elapsed from the trigger timing or after a predetermined number of overhead traveling vehicles 6 are inspected by the inspection device 70.

That is, first, the state information acquisition unit 81 acquires state information of the plurality of overhead traveling vehicles 6 from the inspection device 70 (state information acquisition step: step S1). In step S1, the state information of the plurality of overhead traveling vehicles 6 inspected by the inspection device 70 from the trigger timing to the present time is acquired. Subsequently, the abnormal section estimation unit 83 groups the plurality of overhead traveling vehicles 6 of which the state information has been acquired (step S2). In step S2, based on the state information of the plurality of overhead traveling vehicles 6, the plurality of overhead traveling vehicles 6 are grouped into a first group of damaged overhead traveling vehicles and a second group of undamaged overhead traveling vehicles.

Subsequently, the travel history information acquisition unit 82 acquires, from the data server DS, travel history information of the plurality of overhead traveling vehicles 6 of which the state information has been acquired (travel history information acquisition step: step S3). In step S3, the travel history information of each overhead traveling vehicle 6 is information regarding a travel history in which the overhead traveling vehicle 6 has traveled between the latest inspection (inspection corresponding to the state information in step S1) performed by the inspection device 70 and the previous inspection (inspection immediately before the latest inspection) performed by the inspection device 70.

Subsequently, based on the state information and the travel history information, the abnormal section estimation unit 83 calculates a first frequency at which the plurality of overhead traveling vehicles 6 belonging to the first group (that is, damaged overhead traveling vehicles) have traveled in each section 41, and generates a first heat map H1 (see FIG. 4A) having shading corresponding to the first frequency (step S4). Based on the state information and the travel history information, the abnormal section estimation unit 83 calculates a second frequency at which the plurality of overhead traveling vehicles 6 belonging to the second group (that is, undamaged overhead traveling vehicles) have traveled in each section 41, and generates a second heat map H2 (see FIG. 4A) having shading corresponding to the second frequency.

Subsequently, the abnormal section estimation unit 83 subtracts the second heat map H2 from the first heat map H1 to generate an abnormal section heat map H3 (see FIG. 5) as an estimation of an abnormal section (abnormal section estimation step: step S6). Then, the abnormal section estimation unit 83 displays the generated abnormal section heat map H3 on the display 12 (step S7).

As described above, in the rail guided carriage system 1 and the abnormal section estimation method, when an abnormal section occurs, it is discovered that the state of the overhead traveling vehicle 6 that has traveled in the abnormal section, among the plurality of overhead traveling vehicles 6, changes (the LDM 59 is damaged, the traveling roller 51 is worn, or the like). Therefore, in the rail guided carriage system 1, by evaluating the state information and the travel history information of the plurality of overhead traveling vehicles 6 in association with each other, it is possible to quickly estimate an abnormal section of the track 4 and more reliably prevent the spread of the damage. Before the spread of the damage, it is possible to quickly trace in which section 41 the abnormality has occurred from the state information and the travel history information.

In the rail guided carriage system 1, the state information is information indicating a damage state of the overhead traveling vehicle 6, and the travel history information is information indicating a plurality of sections 41 in which the overhead traveling vehicle 6 has traveled. The abnormal section estimation unit 83 is configured or programmed to group the plurality of overhead traveling vehicles 6 into a first group of damaged overhead traveling vehicles and a second group of undamaged overhead traveling vehicles, and estimate an abnormal section based on at least one of a first frequency at which the plurality of overhead traveling vehicles 6 in the first group have traveled in each of the plurality of sections 41 and a second frequency at which the plurality of overhead traveling vehicles 6 in the second group have traveled in each of the plurality of sections 41. In this case, it is possible to easily estimate an abnormal section of the track 4 by grouping the plurality of overhead traveling vehicles 6 based on whether there is damage.

In the rail guided carriage system 1, the abnormal section estimation unit 83 is configured or programmed to display an abnormal section heat map H3 indicating each of the plurality of sections 41 distinguished according to the difference value between the first frequency and the second frequency on the display 12. This makes it possible to effectively visualize a degree of possibility of abnormality in the abnormal section among the plurality of sections 41.

In the rail guided carriage system 1, the travel history information of the overhead traveling vehicle 6 includes time information. Therefore, the time information included in the travel history information of the overhead traveling vehicle 6 may be used, for example, to weight the state information of the overhead traveling vehicle.

Next, a second example embodiment will be described. In the description of the present example embodiment, differences from the first example embodiment will be described, and redundant description will be appropriately omitted.

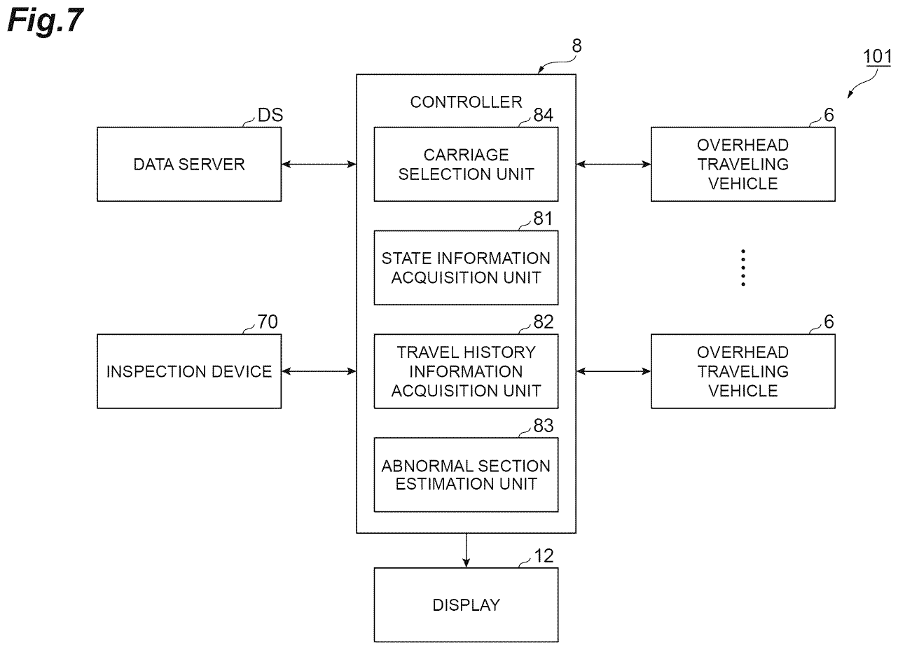

As illustrated in FIG. 7, in a rail guided carriage system 101 according to the second example embodiment, the controller 8 is configured or programmed to further include a carriage selection unit 84 as a functional component. Referring to the travel history information stored in the data server DS, the carriage selection unit 84 is configured or programmed to select some overhead traveling vehicles 6 from among the plurality of overhead traveling vehicles 6. Some overhead traveling vehicles 6 selected by the carriage selection unit 84 (hereinafter, also simply referred to as “some overhead traveling vehicles 6”) are a plurality of carriages related to a combination covering all the sections 41 of the track 4 when the plurality of sections 41 in which the overhead traveling vehicles 6 have traveled are combined. Some overhead traveling vehicles 6 travel so as to cover all the sections 41 of the track 4. That is, when the plurality of sections 41 in which some overhead traveling vehicles 6 have traveled are added together, all the sections 41 of the track 4 are covered.

The state information acquisition unit 81 is configured or programmed to acquire state information of some overhead traveling vehicles 6 from the inspection device 70. When the state information of some overhead traveling vehicles 6 is acquired, the controller 8 may sequentially assign travel commands to some overhead traveling vehicles 6 for causing them to travel to the work area 160, and sequentially inspect some overhead traveling vehicles 6 by the inspection device 70. Alternatively, when the state information of some overhead traveling vehicles 6 is acquired, if the inspection of some overhead traveling vehicles 6 has already been completed by the inspection device 70, the inspection results may be used.

The abnormal section estimation unit 83 is configured or programmed to estimate an abnormal section based on a ratio (hereinafter, also simply referred to as a “damage ratio”) of the number of damaged overhead traveling vehicles to the plurality of overhead traveling vehicles 6 that have traveled in each of the plurality of sections 41 (here, all the sections 41). As an example, when N overhead traveling vehicles 6 travel in a certain section 41, and k (k≤N) overhead traveling vehicles 6 are damaged, the damage ratio of the plurality of overhead traveling vehicles 6 that have traveled in the certain section 41 may be expressed as (k/N)×100. The abnormal section estimation unit 83 is configured or programmed to estimate a section 41 in which the damage ratio is equal to or greater than a threshold among the plurality of sections 41 as an abnormal section. The threshold is a predetermined value, and may be a fixed value or a variable value. When the abnormal section is estimated by the abnormal section estimation unit 83, the controller 8 outputs a (visual and audio) warning indicating that the abnormal section exists, for example, via the display 12 and a speaker (not illustrated).

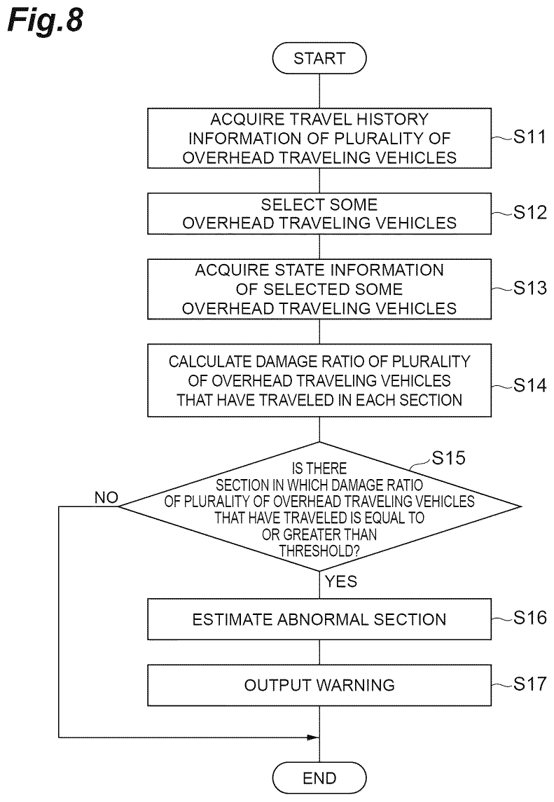

Next, an example pf an abnormal section estimation method performed in the rail guided carriage system 101 will be described with reference to a flowchart of FIG. 8. In the rail guided carriage system 1, for example, a timing scheduled in advance or a timing (manually) operated by an operation is used as a trigger, and the following processing is performed by the controller 8.

That is, first, the travel history information acquisition unit 82 is configured or programmed to acquire travel history information of the plurality of overhead traveling vehicles 6 from the data server DS (step S11). Based on the acquired travel history information of the plurality of overhead traveling vehicles 6, the carriage selection unit 84 is configured or programmed to select some overhead traveling vehicles 6 related to a combination covering all the sections 41 of the track 4 when the plurality of sections 41 in which the plurality of overhead traveling vehicles 6 have traveled are combined (step S12).

Subsequently, the state information acquisition unit 81 is configured or programmed to acquire state information of the selected some overhead traveling vehicles 6 from the inspection device 70 (step S13). In step S13, for example, the controller 8 is configured or programmed to sequentially assign travel commands to some overhead traveling vehicles 6 for causing them to travel to the work area 160, and the inspection device 70 sequentially inspects some overhead traveling vehicles 6, and acquires inspection results as state information.

Subsequently, the abnormal section estimation unit 83 is configured or programmed to calculate a damage ratio of the plurality of overhead traveling vehicles 6 that have traveled in each section 41 based on the state information and the travel history information of some overhead traveling vehicles 6 (step S14). The abnormal section estimation unit 83 is configured or programmed to determine whether there is a section 41 in which the damage ratio of the plurality of overhead traveling vehicles 6 that have traveled is equal to or greater than the threshold (that is, whether at least one of the plurality of sections 41 is highly likely to be abnormal) (step S15). If YES in step S15, the abnormal section estimation unit 83 is configured or programmed to estimate the section 41 in which the damage ratio is equal to or greater than the threshold as an abnormal section (step S16). Then, a (visual and audio) warning indicating that the abnormal section exists is output via, for example, the display 12 and a speaker (not illustrated) (step S17).

In the rail guided carriage system 101, it is discovered that, the greater the bias in the damage ratio (or the ratio of the number of undamaged overhead traveling vehicles 6) of the plurality of overhead traveling vehicles 6 that have traveled (or have not traveled) in a certain section 41, the more likely it is that the section 41 is an abnormal section (or is not an abnormal section). Therefore, the abnormal section estimation unit 83 estimates an abnormal section based on the damage ratio of the plurality of overhead traveling vehicles 6 that have traveled in each of the plurality of sections 41. This makes it possible to easily estimate an abnormal section of the track 4 using the above knowledge.

The rail guided carriage system 101 includes a carriage selection unit 84. The carriage selection unit 84 is configured or programmed to select, from among the plurality of overhead traveling vehicles 6, some overhead traveling vehicles 6 related to a combination covering all the sections of the track 4 when the plurality of sections 41 in which the overhead traveling vehicles 6 have traveled are combined. The state information acquisition unit 81 is configured or programmed to acquire state information of some overhead traveling vehicles 6 selected by the carriage selection unit 84. Based on the travel history information and the state information of some overhead traveling vehicles 6, the abnormal section estimation unit 83 is configured or programmed to estimate, as an abnormal section, a section in which the damage ratio of the plurality of overhead traveling vehicles 6 is equal to or greater than the threshold among all the sections 41. This makes it possible to easily estimate an abnormal section among all the sections 41 of the track 4.

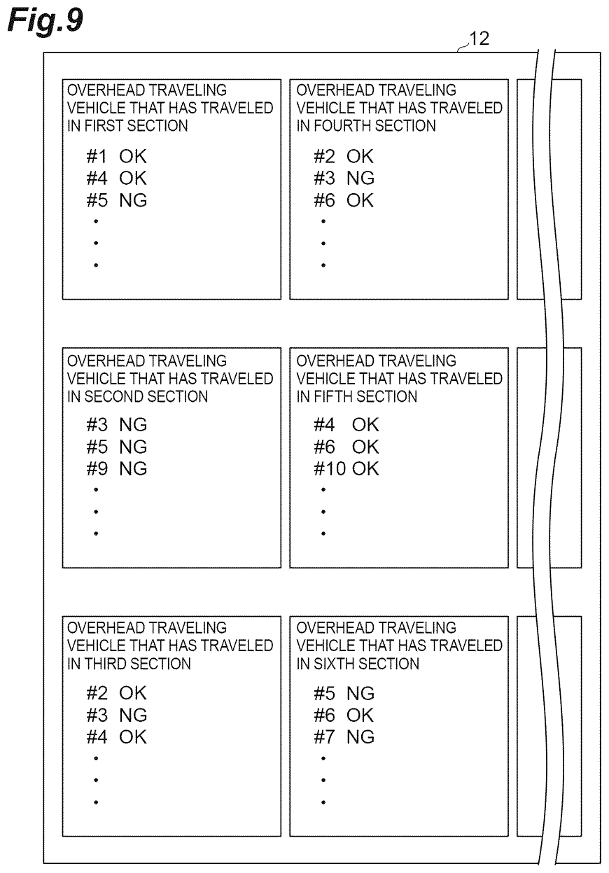

In the present example embodiment, as a display regarding the damage ratio, for example, as illustrated in FIG. 9, the overhead traveling vehicles 6 that have traveled in each section 41 and the states thereof may be displayed on the display 12. In the example of FIG. 9, the number following “#” is an identification number of an overhead traveling vehicle 6. “OK” indicates that the overhead traveling vehicle 6 is not damaged, and “NG” indicates that the overhead traveling vehicle 6 is damaged. This makes it possible for a worker to easily grasp a damage ratio for each section 41.

Although example embodiments have been described above, the present disclosure is not limited to the above-described example embodiments.

In the above-described example embodiments, the state information of the overhead traveling vehicle 6 is not particularly limited, and may be various types of information as long as the information relates to a state of the overhead traveling vehicle 6. For example, the state information may be information regarding whether or not the roller such as the traveling roller 51 is worn, information regarding whether or not dust adheres to the overhead traveling vehicle 6, information regarding various dimensions (a width of the traveling unit 50) of the overhead traveling vehicle 6, information regarding a state in which the location of the occurrence cannot be specified, and the like.

In the first example embodiment, an abnormal section heat map H3 (see FIG. 5) is generated to estimate an abnormal section, but the present disclosure is not limited thereto. For example, an abnormal section may be estimated based on the first heat map H1, and in this case, a second heat map H2 and an abnormal section heat map H3 may not be generated. For example, an abnormal section may be estimated based on the second heat map H2, and in this case, a first heat map H1 and an abnormal section heat map H3 may not be generated. For example, a table indicating a possibility of abnormality for each section 41 may be generated to estimate an abnormal section.

In the above-described example embodiment, the timing at which the estimation of the abnormal section is started (the timing at which the abnormal section estimation method is started) is not particularly limited, but for example, in order to estimate the abnormal section quickly, it is preferable before all the overhead traveling vehicles 6 are damaged, and it may be before half of all the overhead traveling vehicles 6 are damaged. The timing at which the abnormal section estimation method is started may be determined by a trained model using, for example, the number of damaged overhead traveling vehicles 6 and/or the number of undamaged overhead traveling vehicles 6 as parameters. The trained model may be a model automatically set by machine learning. The type and/or configuration of the algorithm used to generate the trained model is not particularly limited. The type of algorithm is, for example, a random forest decision tree, a multilayer perceptron (neural network), or the like. The algorithm is configured or programmed with the number of intermediate layers, the number of units in each layer, the number of branches, an objective variable, an explanatory variable, etc. The type and/or configuration of the algorithm may be generated by deep learning.

In the second example embodiment, an abnormal section is estimated based on the damage ratio of the plurality of overhead traveling vehicles 6 that have traveled in each of the plurality of sections 41. Alternatively or additionally, an abnormal section may be estimated based on the damage ratio of the plurality of overhead traveling vehicles 6 that have not traveled in each of the plurality of sections 41. Alternatively, an abnormal section may be estimated based on the damage ratio (or the ratio of the number of undamaged overhead traveling vehicles 6) of the plurality of overhead traveling vehicles 6 that have traveled (or have not traveled) in each of the plurality of sections 41.

In the above-described example embodiments, the controller 8 may include only one electronic control unit or may include a plurality of electronic control units. The data server DS may be a part of the controller 8. In the above-described example embodiments, the travel history information is information regarding a travel history in which the overhead traveling vehicle 6 has traveled from the previous inspection performed by the inspection device 70 to the latest inspection performed by the inspection device 70, but is not limited thereto, and may be information regarding a travel history for a predetermined period of time.

While example embodiments of the present invention have been described above, it is to be understood that variations and modifications will be apparent to those skilled in the art without departing from the scope and spirit of the present invention. The scope of the present invention, therefore, is to be determined solely by the following claims.

1-6. (canceled)

7. A rail guided carriage system comprising:
a plurality of carriages to selectively travel in a plurality of sections of a track; and
a controller configured or programmed to include:
a state information acquisition unit configured or programmed to acquire state information of the plurality of carriages;
a travel history information acquisition unit configured or programmed to acquire travel history information of the plurality of carriages; and
an abnormal section estimation unit configured or programmed to estimate an abnormal section based on the state information acquired by the state information acquisition unit and the travel history information acquired by the travel history information acquisition unit, the abnormal section being a section in which an abnormality has occurred among the plurality of sections.

8. The rail guided carriage system according to claim 7, wherein
the state information includes information indicating damage states of the carriages;
the travel history information includes information indicating a plurality of sections in which the carriages have traveled; and
the abnormal section estimation unit is configured or programmed to:
group the plurality of carriages into a first group of damaged carriages and a second group of undamaged carriages; and
estimate the abnormal section based on at least one of a first frequency at which the plurality of carriages in the first group have traveled in each of the plurality of sections and a second frequency at which the plurality of carriages in the second group have traveled in each of the plurality of sections.

9. The rail guided carriage system according to claim 8, wherein the abnormal section estimation unit includes a display unit configured or programmed to display a heat map indicating each of the plurality of sections distinguished according to a difference value between the first frequency and the second frequency.

10. The rail guided carriage system according to claim 7, wherein
the state information includes information indicating damage states of the carriages;
the travel history information includes information indicating a plurality of sections in which the carriages have traveled; and
the abnormal section estimation unit is configured or programmed to estimate the abnormal section based on a ratio of a number of damaged or undamaged carriages with respect to the plurality of carriages that have traveled or have not traveled in each of the plurality of sections.

11. The rail guided carriage system according to claim 10, wherein the controller is configured or programmed to further include:
a carriage selection unit configured or programmed to select, from among the plurality of carriages, some carriages related to a combination covering all the plurality of sections of the track when the plurality of sections in which the some carriages have traveled are combined; wherein
the state information acquisition unit is configured or programmed to acquire state information of the some carriages selected by the carriage selection unit; and
the abnormal section estimation unit is configured or programmed to estimate, as the abnormal section, a section in which a ratio of a number of damaged carriages with respect to the plurality of carriages that have traveled is equal to or greater than a threshold, among all of the plurality of sections.

12. A method for estimating an abnormal section that is a section in which an abnormality has occurred in a rail guided carriage system in which a plurality of carriages selectively travel in a plurality of sections of a track, the method comprising:
acquiring state information of the plurality of carriages;
acquiring travel history information of the plurality of carriages; and
estimating an abnormal section based on the state information acquired in the acquiring state information and the travel history information acquired in the acquiring travel history information, the abnormal section being a section in which an abnormality has occurred among the plurality of sections.
